(19) United States
(12) Patent Application Publication
(10) Pub. No.: US 2022/0252063 A1
(43) Pub. Date: Aug. 11, 2022

(54) ACTUATOR AND FLUID CONTROL DEVICE

(71) Applicant: Murata Manufacturing Co., Ltd., Kyoto (JP)

(72) Inventors: Yutoku KAWABATA, Kyoto (JP); Nobuhira TANAKA, Kyoto (JP)

(21) Appl. No.: 17/660,882

(22) Filed: Apr. 27, 2022

Related U.S. Application Data
(63) Continuation of application No. PCT/JP2020/033359, filed on Sep. 3, 2020.

(30) Foreign Application Priority Data
Nov. 28, 2019 (JP) 2019-215163

(51) Int. Cl. F04B 43/04

(52) U.S. Cl. CPC F04B 43/046; H01L 41/09

(57) ABSTRACT

An actuator includes a first main plate at which a piezoelectric element is disposed, a frame body, and a connection part. The frame body is disposed on an outer side of an outer edge of the first main plate and apart from the first main plate. The connection part is disposed between the first main plate and the frame body. The connection part has a plurality connection bodies and a gap, which are disposed along the outer edge, the plurality of connection bodies being connected to the first main plate and the frame body, the gap being disposed between the plurality of connection bodies. The first main plate and the connection bodies are made of the same material. A thickness of the connection bodies is more than a thickness of the first main plate.

### CROSS REFERENCE TO RELATED APPLICATION

This is a continuation of International Application No. PCT/JP2020/033359 filed on Sep. 3, 2020 which claims priority from Japanese Patent Application No. 2019-215163 filed on Nov. 28, 2019. The contents of these applications are incorporated herein by reference in their entireties.

### BACKGROUND OF THE DISCLOSURE

### Field of the Disclosure

The present disclosure relates to an actuator including a plate that vibrates and a mechanism that supports the plate so that the plate can vibrate, and to a fluid control device including the actuator.

### Description of the Related Art

Patent Document 1 describes a fluid control device including a diaphragm unit. The diaphragm unit in Patent Document 1 includes a diaphragm, a frame plate, and a connection part. The frame plate has a shape surrounding an outer edge of the diaphragm. The connection part connects the outer edge of the diaphragm and the frame plate to each other.

Here, the connection part has an easily deformable shape and elastically supports the diaphragm. Therefore, even if the frame plate is fixed, the diaphragm can perform a predetermined bending vibration.
Patent Document 1: Japanese Unexamined Patent Application Publication No. 2013-57247

### BRIEF SUMMARY OF THE DISCLOSURE

However, since a connection part such as the connection part in Patent Document 1 has an easily deformable shape, the connection part tends to be damaged due to, for example, external shock. When, due to an operation of a pump, which is an example of a fluid control device, a pressure difference occurs between an upper surface and a lower surface of the actuator (an upper surface and a lower surface of the diaphragm) including the diaphragm and the connection part, the connection part is deformed, as a result of which a stress is produced in a drive body disposed on the diaphragm, and thus the drive body tends to be damaged.

Therefore, an object of the present disclosure is to provide an actuator that is not easily damaged while realizing a desired vibration.

An actuator of the disclosure includes a first main plate, a frame body, a connection part, and a drive body. The frame body is disposed on an outer side of an outer edge of the first main plate and apart from the first main plate. The connection part is disposed between the first main plate and the frame body. The drive body is disposed at the first main plate, and causes the first main plate to perform a bending vibration. The connection part has a connection body and a gap that are disposed along the outer edge, the connection body being connected to the first main plate and the frame body, the gap being adjacent to the connection body. The first main plate and the connection body are made of a same material. An average thickness of the connection body is more than an average thickness of the first main plate.

In this structure, since the connection body is thick, the structural durability of the connection body with respect to an external force is increased and thus the connection body is not easily damaged. Since a vibration that is a feature of the actuator is produced at the first main plate, a predetermined vibration can be obtained.

According to the disclosure, it is possible to realize an actuator that is not easily damaged while realizing a desired vibration.

### BRIEF DESCRIPTION OF THE SEVERAL VIEWS OF THE DRAWINGS

FIG. 1 is an exploded perspective view of a fluid control device including an actuator according to a first embodiment.

FIG. 2 is a sectional view showing a structure of the fluid control device according to the first embodiment.

FIG. 3 is a plan view of a flat plate including a first main plate of the actuator according to the first embodiment.

FIGS. 4A, 4B, and 4C are each a sectional view showing a derived example of a supporting mode of the first main plate of the actuator according to the first embodiment.

FIG. 5 is a sectional view showing a structure of a fluid control device according to a second embodiment.

FIG. 6 is a sectional view showing a structure of a fluid control device according to a third embodiment.

FIG. 7 is a sectional view showing a structure of a fluid control device according to a fourth embodiment.

FIG. 8 is a sectional view showing a structure of a fluid control device according to a fifth embodiment.

FIG. 9 is a plan view showing another example of a flat plate including a first main plate of an actuator.

### DETAILED DESCRIPTION OF THE DISCLOSURE

### First Embodiment

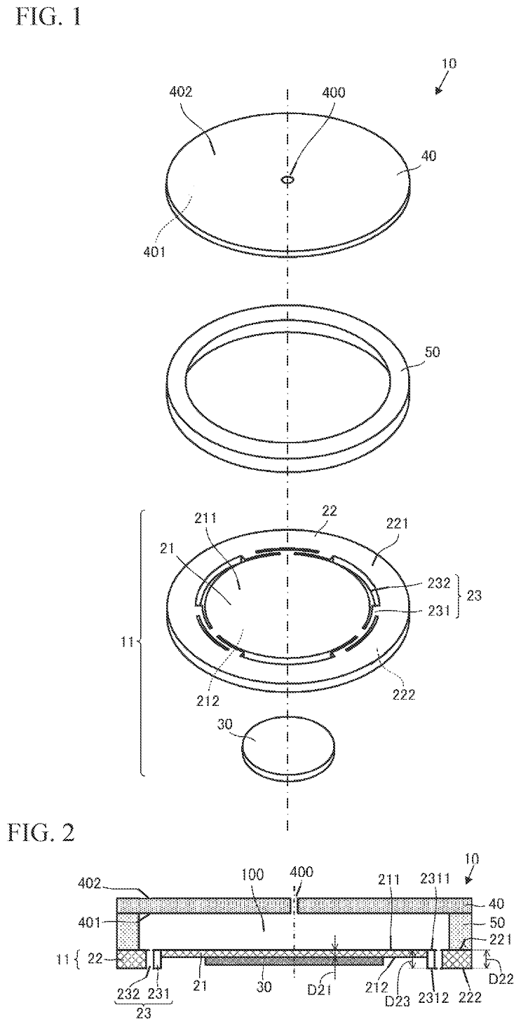

A fluid control device according to a first embodiment of the present disclosure is described with reference to the drawings. FIG. 1 is an exploded perspective view of the fluid control device including an actuator according to the first embodiment. FIG. 2 is a sectional view showing a structure of the fluid control device according to the first embodiment. FIG. 3 is a plan view of a flat plate including a first main plate of the actuator according to the first embodiment. Note that, in FIG. 3, differences in thicknesses are denoted by differences in hatching.

In each figure showing a corresponding one of the embodiments below, for clarity, the shape of each structural element is partly or in its entirety illustrated in an exaggerated manner. For easily understanding the drawings, some reference signs of structural elements that can be univocally conjectured are omitted.

(Structure of Fluid Control Device 10)

As shown in FIGS. 1 and 2, a fluid control device 10 includes a first main plate 21, a frame body 22, a connection part 23, a piezoelectric element 30, a second main plate 40, and a connection member 50. The piezoelectric element 30 corresponds to a “drive body” in the present disclosure. The first main plate 21, the frame body 22, the connection part 23, and the piezoelectric element 30 constitute an actuator 11.

As shown in FIGS. 1 and 3, the first main plate 21 is a flat plate having a circular shape in plan view. The first main plate 21 has a circular first main surface 211 and a circular second main surface 212. The first main surface 211 and the second main surface 212 face each other. The first main plate 21 is made of, for example, a metal. The first main plate 21 is one that performs a bending vibration due to a distortion of the piezoelectric element 30 described below. “Bending vibration” is a vibration in which the first main surface 211 and the second main surface 212 are displaced in a wavelike manner in the side view of the first main plate 21.

The frame body 22 is a flat plate, and the shape of the frame body 22 in plan view is such that an inner peripheral shape is a circular ring shape. The frame body 22 has a ring-shaped first main surface 221 and a ring-shaped second main surface 222. The first main surface 221 and the second main surface 222 face each other. The frame body 22 is disposed on an outer side of an outer edge of the first main plate 21. The frame body 22 is disposed away from the outer edge of the first main plate 21, and, in plan view, surrounds the first main plate 21. That is, the first main plate 21 is disposed in a space situated on an inner side of an inner peripheral end of the frame body 22.

The connection part 23 is disposed between the first main plate 21 and the frame body 22. The connection part 23 is disposed in a peripheral direction of the outer edge of the first main plate 21. More specifically, the connection part 23 has a plurality of connection bodies 231 and a plurality of gaps 232. The plurality of connection bodies 231 and the plurality of gaps 232 are alternately disposed adjacently to each other in the peripheral direction of the outer edge of the first main plate 21. The plurality of connection bodies 231 are connected to the outer edge of the first main plate 21 and the inner peripheral end of the frame body 22, and form a beam. The gaps 232 are arc-shaped grooves in plan view extending from the first main surface 211 of the first main plate 21 and the first main surface 221 of the frame body 22 to the second main surface 212 of the first main plate 21 and the second main surface 222 of the frame body 22.

The first main plate 21, the frame body 22, and the plurality of connection bodies 231 are integrally formed from one plate. That is, the first main plate 21, the frame body 22, and the plurality of connection bodies 231 are formed by forming the plurality of gaps 232 in one plate and forming the external shape of the frame body 22. Therefore, the first main plate 21, the frame body 22, and the plurality of connection bodies 231 are made of the same material. Note that the number of connection bodies 231 is not limited to three and may be four or more.

Due to such a structure, the first main plate 21 is held by the connection part 23 (more specifically, the plurality of connection bodies 231) so that the first main plate 21 can vibrate with respect to the frame body 22.

The piezoelectric element 30 includes a disc piezoelectric body and driving electrodes. The driving electrodes are formed on two main surfaces of the disc piezoelectric body.

The piezoelectric element 30 is disposed on the second main surface 212 of the first main plate 21. Here, in plan view, the center of the piezoelectric element 30 and the center of the first main plate 21 substantially coincide with each other. The piezoelectric element 30 is distorted by applying a drive signal to the driving electrodes. The first main plate 21 performs a bending vibration due to this distortion.

Due to the structure above, the actuator 11 that realizes a predetermined function due to the bending of the first main plate 21 is provided.

The second main plate 40 is a circular flat plate in plan view. It is desirable that the second main plate 40 be made of a material with a thickness, etc. that hardly performs a bending vibration. The external shape of the second main plate 40 has a size that includes the external shape of a portion including the first main plate 21, the connection part 23, and the frame body 22. The second main plate 40 has a circular main surface 401 and a circular main surface 402. The main surface 401 and the main surface 402 face each other.

The second main plate 40 includes a through hole 400. The main-surface-401 side and the main-surface-402 side of the second main plate 40 communicate with each other via the through hole 400. The through hole 400 is disposed at a position overlapping the center of the second main plate 40. Note that the position where the through hole 400 is disposed is not limited to the position overlapping the center of the second main plate 40. For example, there may be a plurality of through holes 400, and the plurality of through holes 400 may be disposed in the form of a ring around the center of the second main plate as an origin.

The second main plate 40 is disposed so that, with respect to the first main plate 21, their main surfaces are in parallel. Here, the main surface 401 of the second main plate 40 and the first main surface 211 of the first main plate 21 face each other. The center of the second main plate 40 in plan view and the center of the first main plate 21 in plan view substantially coincide with each other.

The connection member 50 is a ring-shaped cylindrical body. It is desirable that the connection member 50 be made of a material with a thickness, etc. that hardly performs a bending vibration. The connection member 50 is disposed between the frame body 22 and the second main plate 40. One end of the connection member 50 in a height direction is connected to the first main surface 221 of the frame body 22. The other end of the connection member 50 in the height direction is connected to the main surface 401 of the second main plate 40. Note that the connection member 50 may be formed separately from or integrally with the frame body 22 or the second main plate 40.

Due to this structure, the fluid control device 10 includes a space surrounded by a flat plate, the second main plate 40, and the connection member 50, the flat plate including the first main plate 21, the plurality of connection bodies 231 of the connection part 23, and the frame body 22. In this space, a space interposed between the first main plate 21 and the second main plate 40 is substantially a pump chamber 100 of the fluid control device 10. The pump chamber 100 communicates with the through hole 400 and the plurality of gaps 232 of the connection part 23. In other words, the pump chamber 100 communicates with the outside space of the fluid control device 10 via the through hole 400 and the plurality of gaps 232 of the connection part 23.

In such a structure, due to a bending vibration of the first main plate 21, a pressure distribution occurs inside the pump chamber 100. Due to the bending vibration of the first main plate 21, the pressure distribution inside the pump chamber 100 changes with time, and the fluid control device 10 can transport a fluid in a direction parallel to the first main surface 211 of the first main plate 21. Therefore, for example, the fluid control device 10 can suck a fluid from the gaps 232 and discharge the fluid from the through hole 400. Alternatively, the fluid control device 10 can transport a fluid in an opposite direction.

(More Specific Description of Supporting Structure of First Main Plate 21)

As shown in FIG. 2, a thickness D23 of the plurality of connection bodies 231 is more than a thickness D21 of the first main plate 21. Note that, in the present embodiment, since the thickness of the first main plate 21 is constant, the average thickness of the first main plate 21 is the same as the thickness D21.

Due to such a structure, the plurality of connection bodies 231 configured to hold the first main plate 21 so that the first main plate 21 can vibrate are thick and are not easily deformed. Therefore, the structural durability of the plurality of connection bodies 231 with respect to an external force is increased. That is, the plurality of connection bodies 231 are not easily broken or cracked by an external force. On the other hand, a vibration for realizing a desired function of the actuator 11 and the fluid control device 10 is realized by a bending vibration of the first main plate 21. Therefore, due to this structure being realized, a bending vibration of the first main plate 21 required for the actuator 11 and the fluid control device 10 can be ensured.

Consequently, the actuator 11 and the fluid control device 10 of the present embodiment are not easily damaged while realizing a desired vibration, and the reliability of the actuator 11 and the fluid control device 10 of the present embodiment is enhanced. Further, when, due to an operation of a pump, which is an example of the fluid control device 10, a pressure difference occurs between an upper surface and a lower surface of the actuator (the first main surface 211 and the second main surface 212 of the first main plate 21) including the first main plate 21 and the plurality of connection bodies 231, a stress toward the piezoelectric element 30 caused by deformation of the connection bodies 231 can be suppressed. Therefore, the damage to the piezoelectric element 30 can be suppressed. Consequently, the reliability of the fluid control device 10 is further enhanced.

The structure of the present embodiment has the following features. As shown in FIG. 2, a thickness D22 of the frame body 22 is the same as the thickness D23 of the plurality of connection bodies 231. Therefore, any vibration that leaks to the frame body 22 is suppressed. Consequently, compared with when the frame body 22 is thin, the efficiencies of the actuator 11 and the fluid control device 10 are increased. Note that the thickness D22 of the frame body 22 is to be more than or equal to the thickness D23 of the plurality of connection bodies 231, and, as the thickness D23 increases, the leakage of the vibration can be suppressed. “Thickness” here refers to the average thickness, and as shown in FIG. 2, if the thickness is constant, the thickness is the same as the average thickness. This concept is also applied to other portions of the present application.

In the structure of the present embodiment, the first main surface 211 of the first main plate 21, the first main surface 221 of the frame body 22, and first main surfaces 2311 of the plurality of connection bodies 231 are flush with each other. On the other hand, the second main surface 222 of the frame body 22 and second main surfaces 2312 of the plurality of connection bodies 231 are flush with each other, and the second main surface 212 of the first main plate 21 is situated closer than the second main surface 222 of the frame body 22 and the second main surfaces 2312 of the plurality of connection bodies 231 to the first main surface 211 of the first main plate 21.

In this structure, since at least a part of the piezoelectric element 30 is disposed inside a space formed by a step between the second main surfaces 2312 of the plurality of connection bodies 231 and the second main surface 212 of the first main plate 21, the actuator 11 and the fluid control device 10 can be made thin.

(Derived Example of Supporting Mode of First Main Plate 21)

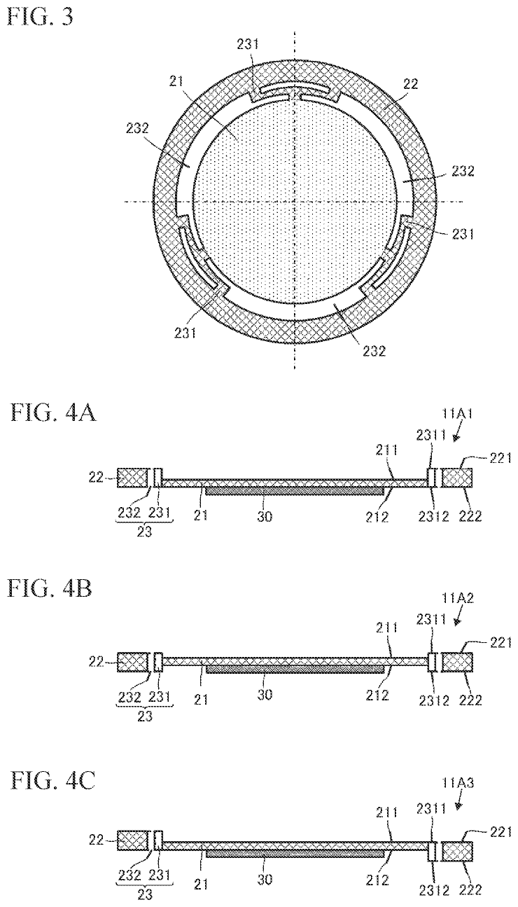

FIGS. 4A, 4B, and 4C are each a sectional view showing a derived example of a supporting mode of the first main plate of the actuator according to the first embodiment.

In the mode in FIG. 4A, an actuator 11A1 is such that a second main surface 212 of a first main plate 21, a second main surface 222 of a frame body 22, and second main surfaces 2312 of a plurality of connection bodies 231 are flush with each other. In this structure, a first main surface 211 of the first main plate 21 is positioned closer than first main surfaces 2311 of the plurality of connection bodies 231 to the second main surface 212 of the first main plate 21. Therefore, as long as the structure of the fluid control device described above is used, the volume of a pump chamber 100 can be increased.

In the mode in FIG. 4B, an actuator 11A2 is such that a first main plate 21 is connected to midway positions on a plurality of connection bodies 231 in a thickness direction thereof. In the mode in FIG. 4C, an actuator 11A3 is such that a first main plate 21 is connected to one connection body 231 so that a second main surface 212 is flush with a second main surface 2312. In addition, the first main plate 21 is connected to the other connection body 231 so that a first main surface 211 is flush with a first main surface 2311. Even with these structures, it is possible to realize such a structure that is not easily damaged while realizing the aforementioned desired vibration.

### Second Embodiment

A fluid control device according to a second embodiment of the present disclosure is described with reference to the drawings. FIG. 5 is a sectional view showing a structure of the fluid control device according to the second embodiment.

As shown in FIG. 5, a fluid control device 10B according to the second embodiment differs from the fluid control device 10 according to the first embodiment in the structure of an actuator 11B. The other structures of the fluid control device 10B are the same as those of the fluid control device 10, and the same portions are not described.

The actuator 11B includes a first main plate 21B. The first main plate 21B has a first region 201 and a second region 202. The first region 201 and the second region 202 are disposed in this order from the center to an outer edge of the first main plate 21B. In other words, the first region 201 is a region that does not include the outer edge of the first main plate 21B, and the second region 202 is a region that surrounds the first region 201 and that includes the outer edge of the first main plate 21B.

A thickness D201 of the first region 201 is more than a thickness D202 of the second region 202. Main surfaces, situated on a pump-chamber-100 side, of the first region 201 and the second region 202 are connected so as to be flush with each other, and constitute a first main surface 211. A second main surface 2012 of the first region 201 is disposed further away than a second main surface 2022 of the second region 202 from the first main surface 211.

A piezoelectric element 30 is disposed on the second main surface 2012 of the first region 201.

In such a structure, in order to obtain a predetermined resonance frequency, the first main plate 21B can be made thin. Therefore, the vibration displacement of the first main plate 21B can be increased. Consequently, for example, the drive voltage of the piezoelectric element 30 can be reduced, and the efficiencies of the actuator 11B and the fluid control device 10B can be increased.

Here, since the thickness D202 of the second region 202 is less than the average thickness of the first main plate 21B, the vibration displacement near the outer edge of the first main plate 21B can be further increased. Therefore, the efficiencies of the actuator 11B and the fluid control device 10B can be further increased.

Since the first main surface 211 of the first main plate 21B is flat from the center to the outer edge, that is, the entire surface on the pump-chamber-100 side is a flat surface, the plane area of the pump chamber 100 that substantially affects the function of fluid control (fluid transport) of the fluid control device 10 can be increased, and the volume can be increased. Therefore, the efficiency of the fluid control device 10B can be further increased.

In the structure of the actuator 11B, an upper end surface (the first main surface 211) of the first main plate 21B in a thickness direction, upper end surfaces (first main surfaces 2311) of connection bodies 231 in the thickness direction, and an upper end surface (a first main surface 221) of a frame body 22 in the thickness direction are flush with each other. Further, a lower end surface (the second main surface 2012 of the first region 201) of the first main plate 21B in the thickness direction, lower end surfaces (second main surfaces 2312) of the connection bodies 231 in the thickness direction, and a lower end surface (a second main surface 222) of the frame body 22 in the thickness direction are flush with each other. Therefore, the thicknesses of the first main plate 21B, the connection bodies 231, and the frame body 22 can be stably provided and a structural body thereof can be formed. Consequently, variations in vibration characteristics of the actuator 11B can be reduced.

### Third Embodiment

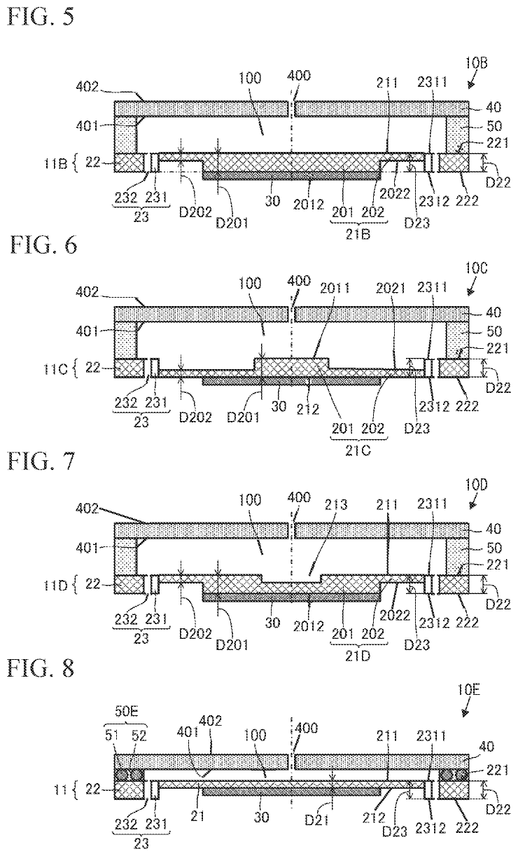

A fluid control device according to a third embodiment of the present disclosure is described with reference to the drawings. FIG. 6 is a sectional view showing a structure of the fluid control device according to the third embodiment.

As shown in FIG. 6, a fluid control device 10C according to the third embodiment differs from the fluid control device 10 according to the first embodiment in the structure of an actuator 11C. The other structures of the fluid control device 10C are the same as those of the fluid control device 10, and the same portions are not described.

The actuator 11C includes a first main plate 21C. The first main plate 21C has a first region 201 and a second region 202. The first region 201 and the second region 202 are disposed in this order from the center to an outer edge of the first main plate 21C.

A thickness D201 of the first region 201 is more than a thickness D202 of the second region 202. Main surfaces, situated on a side opposite to a pump-chamber-100 side, of the first region 201 and the second region 202 are connected so as to be flush with each other, and constitute a second main surface 212. A first main surface 2011 of the first region 201 is disposed further away than a first main surface 2021 of the second region 202 from the second main surface 212.

A piezoelectric element 30 is disposed on the second main surface 212, and, in plan view, partly overlaps the first region 201.

In such a structure, as with the fluid control device 10B according to the second embodiment, the vibration displacement of the first main plate 21C can be increased. Therefore, the efficiencies of the actuator 11C and the fluid control device 10C can be increased.

Here, it is desirable that the thickness D202 of the second region 202 be less than the average thickness of the first main plate 21C. Due to such a structure, the vibration displacement near the outer edge of the first main plate 21C can be further increased. Therefore, the efficiencies of the actuator 11C and the fluid control device 10C can be further increased.

In the structure of the actuator 11C, an upper end surface (the first main surface 2011 of the first region 201) of the first main plate 21C in a thickness direction, upper end surfaces (first main surfaces 2311) of connection bodies 231 in the thickness direction, and an upper end surface (a first main surface 221) of a frame body 22 in the thickness direction are flush with each other. Further, a lower end surface (the second main surface 212) of the first main plate 21C in the thickness direction, lower end surfaces (second main surfaces 2312) of the connection bodies 231 in the thickness direction, and a lower end surface (a second main surface 222) of the frame body 22 in the thickness direction are flush with each other. Therefore, the thicknesses of the first main plate 21C, the connection bodies 231, and the frame body 22 can be stably provided and a structural body thereof can be formed. Consequently, variations in vibration characteristics of the actuator 11C can be reduced.

### Fourth Embodiment

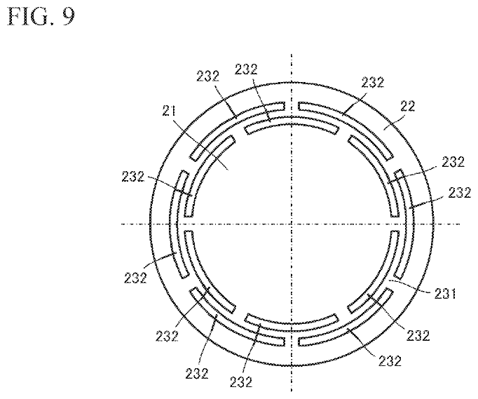

A fluid control device according to a fourth embodiment of the present disclosure is described with reference to the drawings. FIG. 7 is a sectional view showing a structure of the fluid control device according to the fourth embodiment.

As shown in FIG. 7, a fluid control device 10D according to the fourth embodiment differs from the fluid control device 10B according to the second embodiment in the structure of an actuator 11D. The other structures of the fluid control device 10D are the same as those of the fluid control device 10B, and the same portions are not described.

The actuator 11D differs from the actuator 11B according to the second embodiment in that the actuator 11D includes a first main plate 21D. The other structures of the actuator 11D are the same as those of the actuator 11B, and the same portions are not described.

The first main plate 21D differs from the first main plate 21B according to the second embodiment in that the first main plate 21D has a recessed portion 213. The other structures of the first main plate 21D are the same as those of the first main plate 21B, and the same portions are not described.

The recessed portion 213 has a cylindrical shape including the center of a first region 201, that is, the center of the first main plate 21D. The recessed portion 213 has a shape that is recessed from a first main surface 211 in the first region 201. Here, it is desirable that the shape of the recessed portion 213 be set in a range in which a thickness D202 of a second region 202 is less than the average thickness of the first region 201.

Even with such a structure, the actuator 11D and the fluid control device 10D provide the same operational effects as those of the actuator 11B and the fluid control device 10B described above. Further, due to such a structure, the fluid control device 10D can suppress the contact of a central portion of the first main plate 21D with a second main plate 40 caused by a bending vibration of the first main plate 21D.

### Fifth Embodiment

A fluid control device according to a fifth embodiment of the present disclosure is described with reference to the drawings. FIG. 8 is a sectional view showing a structure of the fluid control device according to the fifth embodiment.

As shown in FIG. 8, a fluid control device 10E according to the fifth embodiment differs from the fluid control device 10 according to the first embodiment in the structure of a connection member 50E. The other structures of the fluid control device 10E are the same as those of the fluid control device 10, and the same portions are not described.

The connection member 50E includes a plurality of beads 51 and an adhesive 52. The plurality of beads 51 have a predetermined particle diameter. Note that the particle diameter of the plurality of beads 51 need not be constant, and may be set as appropriate in accordance with the height of a pump chamber 100.

The connection member 50E is configured to adhere a main surface 401 of a second main plate 40 and a first main surface 221 of a frame body 22 to each other by the adhesive 52. Here, the particle diameter of the plurality of beads 51 mixed with the adhesive 52 provides the distance between the main surface 401 of the second main plate 40 and the first main surface 221 of the frame body 22, that is, the height of the pump chamber 100.

Even with such a structure, the fluid control device 10E can provide the same operational effects as those of the fluid control device 10.

Note that, in the description above, the connection part 23 includes a plurality of connection bodies 231 and a plurality of gaps 232 that are alternately disposed adjacently to each other in a peripheral direction. However, the connection part 23 may include gaps that are adjacent to a connection body in a radial direction (a direction orthogonal to a peripheral direction and a thickness direction). FIG. 9 is a plan view showing another example of a flat plate including a first main plate of an actuator.

As shown in FIG. 9, a connection part has a ring-shaped connection body 231 and a plurality of gaps 232. The ring-shaped connection body 231 has a continuous shape in a full circumference along an outer edge of a first main plate 21. The plurality of gaps 232 have an arc shape, and are disposed adjacently to the ring-shaped connection body 231 in the radial direction orthogonal to the peripheral direction. In other words, the plurality of gaps 232 are disposed between the ring-shaped connection body 231 and the first main plate 21 and between the ring-shaped connection body 231 and a frame body 22.

The plurality of gaps 232 are disposed apart from each other in the peripheral direction. At portions between the plurality of gaps 232, the ring-shaped connection body 231 is connected to the first main plate 21 and the frame body 22. Even the portions between the plurality of gaps 232 can be included in a part of the connection body of the present application.

Even with such a structure, by applying the relationship between the thicknesses described above, the operational effects described above can be realized.

In each of the embodiments described above, although the shape of the first main plate in plan view is a circular shape, even if the shape is a regular polygonal shape, in particular, a regular polygonal shape having many angles, the structures described above can be applied. However, when the first main plate has a circular shape, vibration is produced uniformly around the entire circumference, and thus the vibration efficiency is increased, which is more desirable. Here, it is desirable that an inner edge of the frame body have a circular shape along the outer edge of the first main plate. Due to the inner edge of the frame body having a circular shape, the circular first main plate is easily supported in a balanced manner. In each of the embodiments described above, although an outer edge of the frame body 22 has a circular shape, the external shape of the frame body 22 is not limited to a circular shape and can be set as appropriate.

Although each part described above has a constant thickness, each part described above may partly differ in thickness as long as the difference is within a predetermined range (for example, within a manufacturing error range, an allowable range in terms of performance). In this case, the thickness of each part mentioned above may be considered as the average thickness.

In each of the embodiments described above, the first main plate, the frame body, and the plurality of connection bodies are integrally formed with each other. However, the first main plate and the plurality of connection bodies may be integrally formed with each other, and the frame body may be formed separately from the first main plate and the plurality of connection bodies. Alternatively, the first main plate, the plurality of connection bodies, and the frame body can be formed separately from each other. In this case, a structure that increases the structural durability of the plurality of connection bodies with respect to an external force, for example, a material having a high rigidity is to be used. However, by using the structure according to any one of the embodiments mentioned above, while easily forming the actuator and the fluid control device, the operational effects described above can be realized, which is practically more effective.

The structures of the respective embodiments described above can be combined as appropriate, and operational effects corresponding to each of the combinations can be realized.
10, 10B, 10C, 10D, 10E fluid control device
11, 11A1, 11A2, 11A3, 11B, 11C, 11D actuator
21, 21B, 21C, 21D first main plate
22 frame body
23 connection part
30 piezoelectric element
40 second main plate
50, 50E connection member
51 bead
52 adhesive
100 pump chamber
201 first region
202 second region
211 first main surface of first main plate 21
212 second main surface of first main plate 21
213 recessed portion
221 first main surface of frame body 22
222 second main surface of frame body 22
231 connection body
232 gap
400 through hole
401 main surface of second main plate 40
402 main surface of second main plate 40
2011 first main surface of first region 201
2012 second main surface of first region 201
2021 first main surface of second region 202
2022 second main surface of second region 202
2311 first main surface of connection body 231
2312 second main surface of connection body 231

1. An actuator comprising:
a first main plate;
a frame body disposed on an outer side of an outer edge of the first main plate and apart from the first main plate;
a connection part disposed between the first main plate and the frame body; and
a drive body disposed at the first main plate, and causing the first main plate to perform a bending vibration,
wherein the connection part has a connection body and a gap, the connection body and the gap being disposed along the outer edge, the connection part being connected to the first main plate and the frame body, the gap being adjacent to the connection body,
wherein the first main plate and the connection body comprises a same material, and
wherein an average thickness of the connection body is more than an average thickness of the first main plate.

2. The actuator according to claim 1, wherein an average thickness of the frame body is more than or equal to the average thickness of the connection body.

3. The actuator according to claim 1, wherein the first main plate has a first region not including the outer edge, and a second region surrounding the first region and including the outer edge, and
wherein an average thickness of the first region is more than an average thickness of the second region.

4. The actuator according to claim 3, wherein the average thickness of the second region is less than the average thickness of the first main plate.

5. The actuator according to claim 1, wherein the first main plate, the connection body, and the frame body are integrally provided with each other, and
wherein an upper end of the first main plate in a thickness direction, an upper end of the connection body in the thickness direction, and an upper end of the frame body in the thickness direction are flush with each other, or
a lower end of the first main plate in the thickness direction, a lower end of the connection body in the thickness direction, and a lower end of the frame body in the thickness direction are flush with each other.

6. The actuator according to claim 1, wherein the first main plate has a circular shape.

7. The actuator according to claim 6, wherein an inner edge of the frame body has a circular shape along the outer edge of the first main plate.

8. A fluid control device comprising:
the actuator according to claim 1;
a second main plate disposed away from the first main plate in a direction orthogonal to a main surface of the first main plate; and
a connection member disposed between the second main plate and the frame body, and connected to the second main plate and the frame body,
wherein a main surface of the second main plate is positioned parallel to the main surface of the first main plate,
wherein the second main plate has a through hole extending in a direction orthogonal to the main surface of the second main plate, and
wherein the fluid control device has a pump chamber surrounded by the first main plate, the second main plate, and the connection member, and communicating with an outside via the gap of the connection part and the through hole of the second main plate.

9. The fluid control device according to claim 8, wherein a main surface of the first main plate has a shape having no unevenness, the main surface facing the second main plate.

10. The fluid control device according to claim 8, wherein a main surface of the first main plate has an outer edge recessed more than a center, the main surface facing the second main plate.

11. The actuator according to claim 2, wherein the first main plate has a first region not including the outer edge, and a second region surrounding the first region and including the outer edge, and
wherein an average thickness of the first region is more than an average thickness of the second region.

12. The actuator according to claim 2, wherein the first main plate, the connection body, and the frame body are integrally provided with each other, and
wherein an upper end of the first main plate in a thickness direction, an upper end of the connection body in the thickness direction, and an upper end of the frame body in the thickness direction are flush with each other, or
a lower end of the first main plate in the thickness direction, a lower end of the connection body in the thickness direction, and a lower end of the frame body in the thickness direction are flush with each other.

13. The actuator according to claim 3, wherein the first main plate, the connection body, and the frame body are integrally provided with each other, and
wherein an upper end of the first main plate in a thickness direction, an upper end of the connection body in the thickness direction, and an upper end of the frame body in the thickness direction are flush with each other, or
a lower end of the first main plate in the thickness direction, a lower end of the connection body in the thickness direction, and a lower end of the frame body in the thickness direction are flush with each other.

14. The actuator according to claim 4, wherein the first main plate, the connection body, and the frame body are integrally provided with each other, and
wherein an upper end of the first main plate in a thickness direction, an upper end of the connection body in the thickness direction, and an upper end of the frame body in the thickness direction are flush with each other, or
a lower end of the first main plate in the thickness direction, a lower end of the connection body in the thickness direction, and a lower end of the frame body in the thickness direction are flush with each other.

15. The actuator according to claim 2, wherein the first main plate has a circular shape.

16. The actuator according to claim 3, wherein the first main plate has a circular shape.

17. The actuator according to claim 4, wherein the first main plate has a circular shape.

18. The actuator according to claim 5, wherein the first main plate has a circular shape.

19. A fluid control device comprising:
the actuator according to claim 2;
a second main plate disposed away from the first main plate in a direction orthogonal to a main surface of the first main plate; and
a connection member disposed between the second main plate and the frame body, and connected to the second main plate and the frame body,
wherein a main surface of the second main plate is positioned parallel to the main surface of the first main plate,
wherein the second main plate has a through hole extending in a direction orthogonal to the main surface of the second main plate, and
wherein the fluid control device has a pump chamber surrounded by the first main plate, the second main plate, and the connection member, and communicating with an outside via the gap of the connection part and the through hole of the second main plate.

20. A fluid control device comprising:
the actuator according to claim 3;
a second main plate disposed away from the first main plate in a direction orthogonal to a main surface of the first main plate; and
a connection member disposed between the second main plate and the frame body, and connected to the second main plate and the frame body,
wherein a main surface of the second main plate is positioned parallel to the main surface of the first main plate,
wherein the second main plate has a through hole extending in a direction orthogonal to the main surface of the second main plate, and
wherein the fluid control device has a pump chamber surrounded by the first main plate, the second main plate, and the connection member, and communicating with an outside via the gap of the connection part and the through hole of the second main plate.
